(19) United States
(12) Patent Application Publication
(10) Pub. No.: US 2010/0033911 A1
(43) Pub. Date: Feb. 11, 2010

(54) PORTABLE ELECTRONIC DEVICE

(75) Inventors: CHIH-CHIANG CHANG, Shindian (TW); ZHI LI, Shenzhen City (CN); ZHI-YUN SHEN, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/347,244

(22) Filed: Dec. 31, 2008

(30) Foreign Application Priority Data
Aug. 7, 2008 (CN) 200810303568.5

(51) Int. Cl. H05K 5/00

(52) U.S. Cl. 361/679.01

(57) ABSTRACT

A portable electronic device incorporating a strap for hanging a pendent, comprises a first housing and a second housing. The first housing has a slot defined therein, the slot is used to receive the strap therein. The second housing is secured to the first housing to cover the slot.

### CROSS-REFERENCE TO RELATED APPLICATIONS

This application is related to co-pending U.S. Patent Applications (Attorney Docket No. US21762), entitled “PORTABLE ELECTRONIC DEVICE”, by Chih-Chiang Chang et al. The application has the same assignee as the present application and has been concurrently filed herewith.

### BACKGROUND

1. Technical Field

The present invention relates to portable electronic devices, particularly to portable electronic device with a dangling decorative object, such as a pendant.

2. Description of Related Art

Many portable electronic devices today include dangling decorative objects, such as pendants to enhance external appearances and allow personalization. The decorative object may be attached to the electronic device by a strap, such as twine, wire, string, or rope, etc. The mobile phone defines a hole and the strap may be inserted through the hole and a hole in the decorative object, and the strap circled around and knotted. Thus, the strap forms a loop, thereby hanging the decorative object thereon.

However, it is difficult to insert the strap through the hole because the hole is usually small. Additionally, it is inconvenient to detach the decorative object from the mobile phone by untying the knots.

Therefore, there is room for improvement within the art.

### BRIEF DESCRIPTION OF THE DRAWINGS

Many aspects of the exemplary portable electronic device can be better understood with reference to the following drawings. These drawings are not necessarily drawn to scale, the emphasis instead being placed upon clearly illustrating the principles of the exemplary portable electronic device. Moreover, in the drawings like reference numerals designate corresponding parts throughout the several views. Wherever possible, the same reference numbers are used throughout the drawings to refer to the same or like elements of an embodiment.

FIG. 1 is an illustrative and assembled view of a portable electronic device according to an exemplary embodiment.

FIG. 2 is a partly enlarged view relative to FIG. 1.

FIG. 3 is an exploded view of the portable electronic device in FIG. 1.

### DETAILED DESCRIPTION OF THE EXEMPLARY EMBODIMENTS

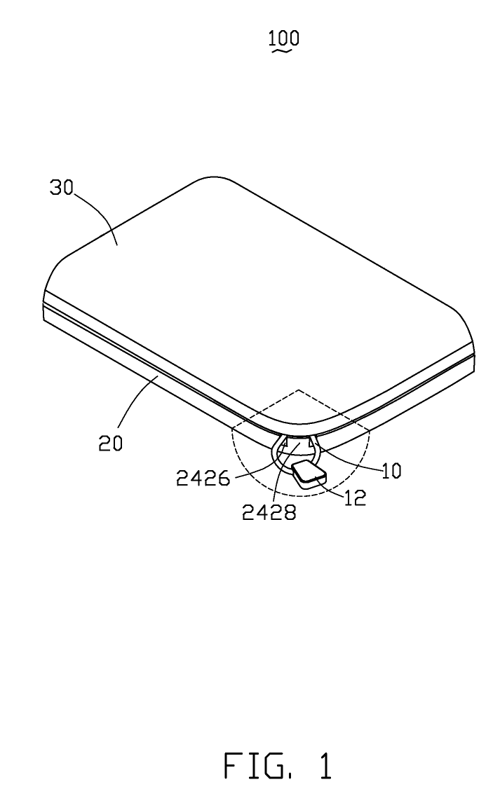

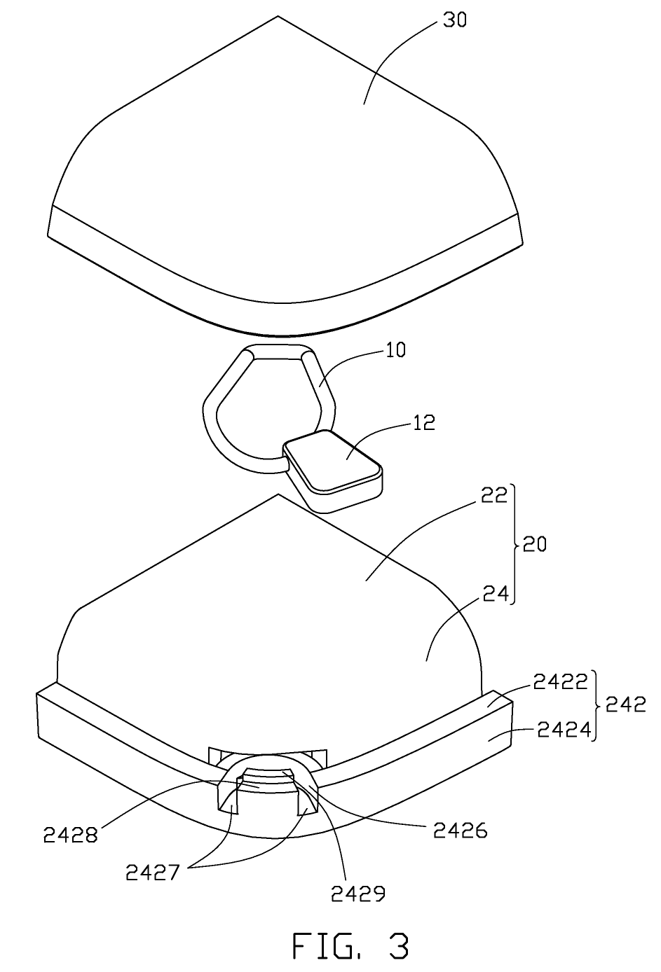

Exemplary embodiments will now be described in detail below and with reference to the drawings. Referring to FIG. 1, a portable electronic device 100 includes a first housing 20, a second housing 30 secured to the first housing 20, and a strap 10 secured between the first housing 20 and the second housing 30. The strap 10 is loop-shaped (see FIG. 3) and may be used for hanging/securing a decorative object 12.

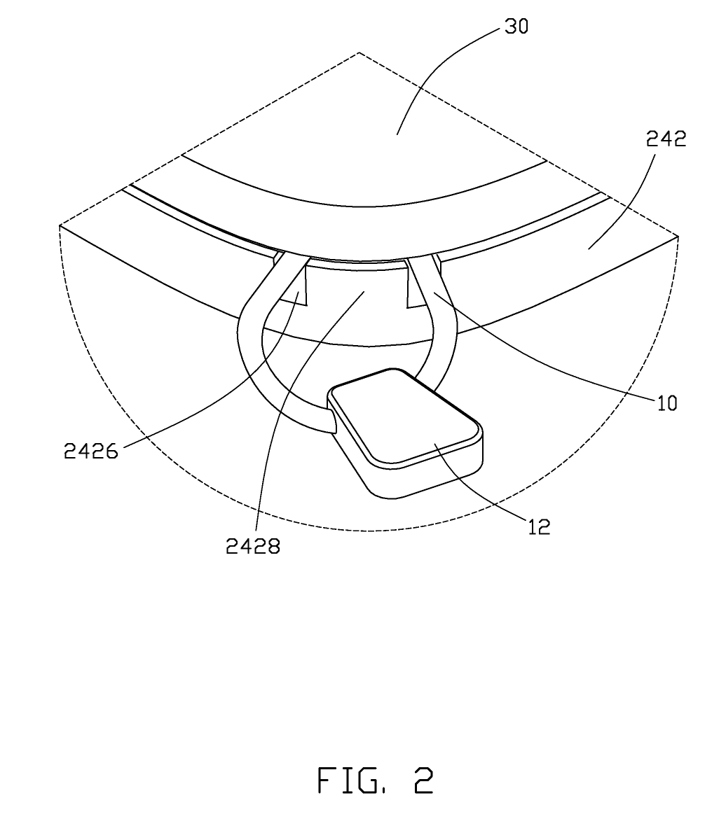

Referring to FIGS. 2 and 3, the first housing 20 includes an upper wall 22 and a round peripheral wall 24 connecting the upper wall 22. The housing 20 further includes a peripheral flange 242 surrounding the peripheral wall 24.

The peripheral flange 242 has a first surface 2422 facing the second housing 30 and a second surface 2424 substantially perpendicular to the first surface 2422. The peripheral flange 242 has a curved, e.g., C-shaped, slot 2426 defined through the first surface 2422 and the second surface 2424. Two adjacent openings 2427 of the slot 2426 expose through the second surface 2424, thus a block 2428 is formed between the two openings 2427 in the peripheral flange 242.

The block 2428 is used to coil the strap 10 around. The block 2248 has a L-shaped cross-section and includes a protrusion 2249 extending from the first surface 2422 of the peripheral flange 242. When the second housing 30 covering the first housing 20, the protrusion 2249 overlaps vertically with the second housing 30 so as to prevent the strap 10 from falling out of the slot 2246, i.e., preventing the strap 10 from sliding out of the slot 2426 through a gap between the first housing 20 and the second housing 30. Thus, the securing of the first housing 20 and the second housing 30 prevents the strap 10 from sliding out of the slot 2426.

To assemble the strap 10 to the portable electronic device 100, the strap 10 can be coiled around the block 2428 and received inside the slots 2426. After that, the second housing 30 is secured to the first housing 20 to cover the slot 2426 and prevents the strap 10 from sliding out of the slot 2426. To detach the strap 10 from the portable electronic device 100, the second housing 30 can be removed from the first housing 20 to expose the slot 2426. Thus, it is easy to release the strap 10 from the block 2428.

It is to be understood, however, that even through numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A portable electronic device incorporating a strap for hanging a decorative object, the portable electronic device comprising:
a first housing having a slot defined therein, the slot receiving the strap therein; and
a second housing secured to the first housing to cover the slot to prevent the strap from falling out of the slot.

2. The portable electronic device as claimed in claim 1, wherein the first housing includes an upper wall and a peripheral wall connecting with the upper wall, the peripheral wall has a peripheral flange extending outwardly therefrom, the slot is defined in the peripheral flange and facing to the second housing.

3. The portable electronic device as claimed in claim 2, wherein the slot is C-shaped.

4. The portable electronic device as claimed in claim 3, wherein the peripheral flange has a first surface facing the second housing and a second surface perpendicular to the first surface, the slot defined in the first surface and thus forming two adjacent and spaced openings in the first surface.

5. The portable electronic device as claimed in claim 3, wherein the two adjacent openings communicate with the second surface, thus a block is formed on the peripheral flange to be used to coil the strap around.

6. The portable electronic device as claimed in claim 5, wherein the block has a protrusion extending the first surface therefrom, the protrusion overlaps vertically with the second housing so as to prevent the strap from falling out of the slot.

7. The portable electronic device as claimed in claim 5, wherein the block has a L-shaped cross-section and includes a protrusion extending therefrom, the protrusion configured for preventing the strap from falling out of the slot when the second housing covering the first housing.

8. A portable electronic device incorporating a strap for hanging a decorative object, the portable electronic device comprising:
a first housing having two adjacent openings defined through a peripheral edge and having a block formed between the two openings, the two openings being configured for partially receiving the strap therein, the block being configured for passing through the strap, the block including a protrusion extending a first surface therefrom; and
a second housing engaging with the first housing and configured to cover the two openings so as to prevent the strap from falling out of the first housing.

9. The portable electronic device as claimed in claim 8, wherein the first housing includes an upper wall and a peripheral wall connecting with the upper wall, the peripheral wall has a peripheral flange extending outwardly therefrom, the two openings are defined in the peripheral flange.

10. The portable electronic device as claimed in claim 9, wherein the peripheral flange has a first surface facing the second housing and a second surface perpendicular to the first surface, a C-shaped slot defined in the first surface and thus forming the two openings in the first surface.

11. The portable electronic device as claimed in claim 10, wherein the two adjacent openings communicate with the second surface, thus a block is formed on the peripheral flange to be used to coil the strap around.

12. The portable electronic device as claimed in claim 11, wherein the block has a protrusion extending the first surface therefrom, the protrusion overlaps vertically with the second housing so as to prevent the strap from falling out of the slot.

13. The portable electronic device as claimed in claim 11, wherein the block has a L-shaped cross-section and includes a protrusion extending therefrom, the protrusion configured for preventing the strap from falling out of the slot when the second housing covering the first housing.
